(19) United States
(12) Patent Application Publication
(10) Pub. No.: US 2019/0206657 A1
(43) Pub. Date: Jul. 4, 2019

(54) A MACHINE AND A PROCESS FOR THE ATMOSPHERIC PLASMA TREATMENT OF DIFFERENT MATERIALS USING GASEOUS MIXTURES COMPRISING CHEMICALS AND/OR MONOMERS

(71) Applicant: GRINP S.R.L., Torino (IT)

(72) Inventors: Parisi FRANCESCO, Torino (IT); Katiuscia COSTABELLO, Torino (IT); Chiara PAVAN, Torino (IT)

(21) Appl. No.: 16/092,957

(22) PCT Filed: Apr. 11, 2016
(86) PCT No.: PCT/IT2016/000091

§ 371 Date: Oct. 11, 2018

(51) Int. Cl. H01J 37/32

(52) U.S. Cl. CPC H01J 37/32348; H01J 37/32825; H01B 3/12; H01J 37/3255; H01J 37/32449

(57) ABSTRACT

The invention relates to a machine for the plasma treatment of various materials comprising a first cathode (1) and a second cathode (2) positioned opposite one to the other, each cathode comprising a plurality of first (3) and second (5) conductor electrodes embedded in portions of dielectrically insulating material (9) and a plurality of channels (7) placed between two adjacent portions of dielectrically insulating material (9) and passing through the second conductor electrodes (5); electrical means apt to generate a first transverse electric field (T) and a second longitudinal electric field (L) between the first cathode (1) and the second cathode (2); supply means (6) apt to supply a gaseous mixture (4) in a region of space traversed by the lines of force of the transverse (T) and longitudinal (L) electric fields, the gaseous mixture (4) being supplied in a uniform manner in said region and the electric fields being such as to trigger the breakdown of the gaseous mixture (4) and generate in this way a plasma in said region.

The invention also relates to the relative processes for the plasma treatment of various materials and a gaseous mixture (4) which can be used for the plasma treatment of various materials comprising chemicals and/or monomers.

### TECHNICAL FIELD

The present invention relates to the textile sector and, specifically, to machines and processes for the atmospheric plasma treatment of different substrates.

More particularly the invention relates to the use of gaseous mixtures comprising chemicals and/or monomers in machines and processes for the atmospheric plasma treatment of different substrates.

In general the invention relates to a machine and to the relative processes according to the preamble of claim 1 for the atmospheric plasma treatment of various materials.

### STATE OF THE ART

Atmospheric plasma treatments provide for the use of a partially ionised gas which can trigger chemical and physical reactions on the surface of a substrate with which it comes into contact in certain conditions and induces transitory and permanent modifications of the same substrate.

The application of the atmospheric plasma technology in the textile field causes particular effects on the fibres and on the fabrics and creates additional functions such as, for example, surface bioactivity, waterproof and anti-felting properties, anti-stain action, the capacity for retaining water, flame-resistant, self-cleaning and anti-mould behaviour which confer to the materials new and commercially interesting features.

Atmospheric plasma processes and machines currently exist for treating substrates of different types using gas, or mixtures of gas, comprising chemicals and/or monomers.

Examples of these machines and processes are described in the international applications published under no. WO 02/23960 A1 and under no. WO 2015/088920 A1 and in the US patent applications no. US 2010/0221451 A1, no. US 2008/0107822 A1 and no. US 2003/0221950 A1.

The document WO 02/23960 A1 describes the constructional concept of a system for producing a glow discharge, which provides for the application of a high electric potential (some hundreds of volts) between two electrodes placed in a cell filled with gas. Consequently a part of atoms in the cell is ionised and, in turn, gives rise to collisions with other atoms, ionising them. The ionisation is accompanied by the excitement of electrons which causes a visible emission, whose wavelength depends on the gas used. In direct current conditions there is no time dependence and, therefore, the ionised gas, or plasma, is a stationary structure. The salient aspect of the invention described in this document is the use of porous material in order to diffuse the gas in the zone of generation of the plasma. This invention also comprises the possibility of using monomers and the system is heated. Some limits of this invention lie in the fact that the system can only work with helium and that the use of complex monomers and which can be polymerised may entail their reaction inside the pores, with consequent closure of the latter and deactivation of the system. More specifically the solution described in this document, although tackling the technical problem of generating an atmospheric plasma for the treatment of various materials using gaseous mixtures comprising monomers, is not however able to meet the production needs of continuous production, which requires short and infrequent machine down times.

The document WO 2015/088920 A1 relates to a system comparable to the technology known as “APJet™”, wherein the gas and the possible monomer are excited far from the zone wherein the substrate passes and flow through the lower electrodes. This type of technology has evident disadvantages in the actual case of deposition, because the excited precursors tend to deposit also on the electrodes present along the path toward the substrate. This phenomenon, as well as reducing the efficiency of the deposition, causes the soiling of the electrodes, making continuous and frequent cleaning thereof necessary, which is not very compatible with production concerns which operate continuously and handle large volumes of materials, such as those of the textiles industry. Moreover this solution involves large volumes of gas, increasing the cost of the treatment.

The document US 2008/0107822 A1 presents a system wherein the monomer is in the form of a spray and is sprayed before and/or after the zone where the plasma is generated, outside of the electric field. The monomer is sprayed and not vaporised on the substrate and therefore does not need heating. The plasma produces very active radicals with short life times. These radicals react therefore fast with the other radicals they meet, whether gases or monomers. The selectivity of the groups which are formed is strongly jeopardised by the enormous quantity of species which are present in the zone of the plasma and this gives rise to highly heterogeneous deposits with low modulation potential, both in terms of thickness and of chemical composition. This solution therefore, which describes a technology similar to that used in the document WO 2015/088920 A1 as above, is found to have similar disadvantages.

The document US 2003/0221950 A1 provides a totally confined and closed system which uses for the polymerisation, as gas in the ionisation chamber, air or a mixture of nitrogen N₂ and oxygen O₂. This solution, however, does not allow continuous working and to have a solution suitable for an in-line production process.

Summing up, the atmospheric systems of plasma deposition according to the prior art, given as examples here above, have disadvantages in terms of maintaining of the chemical structure of the precursor used, which is subjected to high fragmentation, The result that derives therefrom is an effect of grafting of functional groups on the surface, not comparable to what is obtained by means of conventional chemical reactions, such as radical polymerisation.

Moreover, if very voluminous and complex molecules are used to confer properties such as flameproof, anti-stain and antibacterial properties, they are fragmented and lose their intrinsic function, the result in fact of their chemical structure, this resulting in a lack of final performance.

Another disadvantage is represented by the soiling of the electrodes during the process of deposition, consequent to the limits of known technologies in terms of point of injection of the precursor/gas, of configuration of the circuit and/or of materials used for the distribution of the gas, which determine the simultaneous deposition of the thin layer both on the substrate and on the electrodes and on the components of the equipment.

The need therefore remains unfulfilled of generating an atmospheric plasma for the treatment of various materials using gaseous mixtures comprising chemicals and/or monomers which allows the deposition of an ordered and repeated polymeric structure and which is limited to only the surface of the substrate.

The need also remains unfulfilled of preserving the chemical structure both of the precursors and of possible very voluminous and complex molecules with all their functions, avoiding the fragmentation thereof.

Finally the need remains unfulfilled of avoiding the soiling of the electrodes during the process of deposition.

To sum up, until the current time, to the Applicant's knowledge, solutions are not known which allow the depositing of an ordered and repeated structure limited to only the surface of the substrate, the preserving of the chemical structure both of the precursors and of possible very voluminous and complex molecules with all their functions and avoiding the soiling of the electrodes during the process of deposition. Therefore the Applicant, with the machine and the process according to the present invention, intends remedying these shortcomings.

### OBJECTS AND SUMMARY OF THE INVENTION

It is the object of the present invention to overcome the disadvantages of the prior art linked to the generation of atmospheric plasma for the treatment of various materials.

It is also the object of the present invention to overcome the disadvantages of the prior art linked to the generation of atmospheric plasma using gaseous mixtures comprising chemicals and/or monomers.

More specifically the present invention intends to solve the problem of performing the deposition of an ordered and repeated structure which is limited to only the surface of the substrate.

Moreover the present invention intends to solve the problems of preserving of the chemical structure both of the precursors and of possible very voluminous and complex molecules with all their functions and avoiding the soiling of the electrodes during the process of deposition.

In particular the object of the present invention is that of providing a machine for the atmospheric plasma treatment of various materials using gaseous mixtures comprising means for the uniform introduction of the gaseous mixture exactly in the electric fields generated, so as to allow the deposition of an ordered, repeated structure limited to the surface of the substrate, also maintaining the chemical structure both of the precursors and of possible very voluminous and complex molecules with all their functions and avoiding the soiling of the electrodes during the process of deposition.

Moreover the object of the present invention is that of providing a process for the atmospheric plasma treatment of various materials using gaseous mixtures wherein the gaseous mixture is introduced uniformly inside the electric fields generated, so as to allow the deposition in an ordered, repeated structure limited to the surface of the substrate, also maintaining the chemical structure both of the precursors and of possible very voluminous and complex molecules with all their functions and avoiding the soiling of the electrodes during the process of deposition.

Moreover the object of the present invention is that of providing a process for the atmospheric plasma treatment of various materials able to operate both in wet and dry form.

Moreover the object of the present invention is that of providing a gaseous mixture comprising chemicals and/or monomers which can be used for the atmospheric plasma treatment of various materials in the aforementioned machine and/or by means of the aforementioned processes.

The aforementioned and other objects and advantages of the invention, as will be seen from the rest of the description, are achieved with a machine for atmospheric plasma treatment of various materials such as that according to claim 1.

Moreover the aforementioned and other objects and advantages of the invention are achieved with a first process embodiment for atmospheric plasma treatment of various materials such as that according to claim 10.

Moreover the aforementioned and other objects and advantages of the invention are achieved with a second, more general process embodiment for atmospheric plasma treatment of various materials such as that according to claim 12.

Moreover the aforementioned and other objects and advantages of the invention are achieved with a gaseous mixture which can be used for the atmospheric plasma treatment of various materials comprising chemicals and/or monomers such as that according to claim 19.

Preferred embodiments and variants of the machine, of the processes and of the gaseous mixture of the present invention constitute the object of the dependent claims.

More particularly, in a preferred and advantageous embodiment the machine, the processes and the gaseous mixture according to the invention allow the obtaining of the deposition and the fixing of an active ingredient in a single passage, eliminating the use of solvents and the correlated excess of chemical products as well as considerably reducing the energy used.

In a further embodiment the machine, the processes and the gaseous mixture according to the invention allow the preparation of the surfaces of various materials, in particular textile substrates in the form of fibres, yarns, fabrics, nonwovens or other, for successive and complementary operations. In a specific variant the machine, the processes and the gaseous mixture according to the present invention allow the preparation of the surface of a fabric for printing, depositing a thin layer chemically compatible with the dye used and/or chemical product, this improving the definition of the print itself and considerably reducing the consumption of water and of energy.

In a further embodiment the machine, the processes and the gaseous mixture according to the invention allow the conferring to the materials treated of the required final properties, for example antimicrobial, anti-mould, adhesion.

In a further embodiment the machine, the processes and the gaseous mixture according to the invention allow the treating of a substrate already covered by a layer of precursors or monomers which require successive activation or polymerisation by means of a catalyst.

In a further embodiment the machine, the processes and the gaseous mixture according to the invention allow the operating both in wet and dry form.

It is understood that all the appended claims form an integral part of the present description and that each of the technical features claimed in them is optionally independent and usable autonomously with respect to the other aspects of the invention.

It will be immediately clear that innumerable changes may be made to what is described (for example relating to shape, sizes, arrangements and parts with equivalent functions) without departing from the sphere of protection of the invention as claimed in the appended claims.

Advantageously the technical solution according to the present invention allows:
the preparation of surfaces of various materials, in particular textile substrates in the form of fibres, yarns, fabrics, nonwovens, plastic films, panels, powders and substrates with irregular and complex surfaces, such as finished and three-dimensional objects;
the application to operations such as, for example, impregnation, printing (ink jet and traditional), coating, lamination, foaming, spraying;
the obtaining of effects and properties according to the specific need such as, for example, antimicrobial, anti-mould, adhesion behaviour;
the elimination of solvents and the reduction of chemical products, with consequent economic and environmental benefits;
the elimination of catalysts, with consequent solving of the problems of storage and handling;
the reduction in energy and water consumptions in the production cycles;
the containing of the overall dimensions of the plant;
the adaptation to existing processes and machinery.

Further advantageous features will be made clearer by the following description of preferred but not exclusive embodiments, given purely by way of a non-limiting example.

### BRIEF DESCRIPTION OF THE DRAWINGS

The present invention will be described here below by means of some preferred embodiments, given by way of a non-limiting example, with reference to the accompanying drawings. These drawings illustrate different aspects and examples of the present invention and, where appropriate, structures, components, materials and/or elements that are similar in different drawings are denoted by similar reference numerals.

FIG. 1A is a cross section view of a first embodiment of a machine for the atmospheric plasma treatment of various materials according to the present invention;

FIG. 1B represents schematically, in a cross section, some possible alternative embodiments of a machine for the atmospheric plasma treatment of various materials according to the present invention;

FIG. 2 illustrates a first variant of the first embodiment of FIG. 1A;

FIG. 3 illustrates a second variant of the first embodiment of FIG. 1A;

FIG. 4 is a graphic representation of the types of chemical reactions which occur on the surface of a material subjected to atmospheric plasma treatment according to the present invention;

FIG. 5 is a flow diagram which shows the phases of a process for the atmospheric plasma treatment of various materials according to a first embodiment of the present invention;

FIG. 6 is a bar graph which compares the angle of contact of fabrics treated with distilled water and oil and subjected to the process according to the present invention with plasma of helium, of helium and oxygen and with no plasma; and

FIG. 7 is a bar graph which compares the angle of contact of fabrics treated with distilled water and oil and subjected to the process according to the present invention with plasma of helium and subsequent washes with water and with solvent.

### DETAILED DESCRIPTION OF THE INVENTION

While the invention is subject to various changes and alternative constructions, some preferred embodiments are shown in the drawings and will be described here below in detail.

It has to be understood, however, that there is no intention to limit the invention to the specific embodiments illustrated but, on the contrary, the invention intends covering all the changes, alternative constructions and equivalents which fall within the sphere of the invention as defined in the claims.

In the following description, therefore, the use of “for example”, “etc.”, “or” indicates non-exclusive alternatives without any limitation, barring indication otherwise. The use of “also” means “including, but not limited to” unless indicated otherwise. The use of “includes/comprises” means “includes/comprises, but not limited to” unless indicated otherwise.

The machine, the processes and the gaseous mixture of the present invention are based on the innovative concept of providing the addition to the gas to be ionised, i.e. to be transformed into plasma, of at least one chemical substance (for example an active ingredient, a resin, precursor chemical product, a catalyst) and at least one monomer, and also of introducing uniformly the gaseous mixture exactly in the electric fields generated, so as to allow the deposition of an ordered, repeated structure limited to the surface of the substrate, also maintaining the chemical structure both of the precursors and of possible very voluminous and complex molecules with all their functions and avoiding the soiling of the electrodes during the process of deposition.

An important feature of said machine, processes and gaseous mixture lies in the fact that they allow the deposition of thin layers, chemically ordered and homogeneous, on the surface of the substrate to be treated.

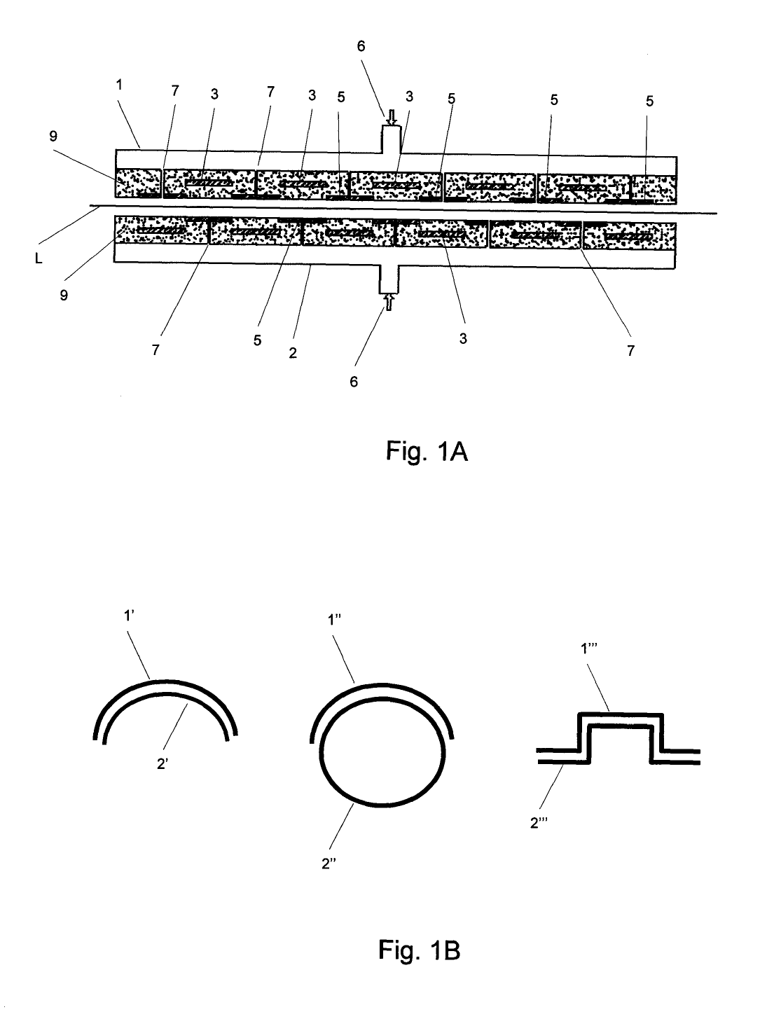

Referring to FIG. 1A, it illustrates a first embodiment of machine for the atmospheric plasma treatment of various materials according to the present invention.

The machine comprises a first cathode 1 and a second cathode 2 which are constructionally identical.

Each cathode 1,2 comprises a plurality of first conductor electrodes 3 and a plurality of second conductor electrodes 5; the first conductor electrodes 3 are embedded inside portions of dielectrically insulating material 9 while the second conductor electrodes 5 are placed emerging on the surface of the cathodes 1,2 on the face of each cathode 1,2 (for example of the first cathode 1) turned towards the other cathode 2,1 (for example of the second cathode 2) and also towards the substrate S to be treated (not shown in the drawing).

The first conductor electrodes 3 and the second conductor electrodes 5 can have different rectangular sections (such as for example illustrated in FIG. 1A), the sizes being able to vary between 0.1 mm by 10 mm and 0.1 mm by 40 mm. Alternatively the first and second conductors 3 and 5 can also be filaments, preferably of diameter equal to 0.3 mm, such diameter being able to vary between 0.1 mm and 1 mm.

Two adjacent first conductor electrodes 3 are spaced one in relation to the other by a distance equal to the distance at which two adjacent second conductor electrodes 3 are spaced in such a way that, if the first conductor electrodes 3 were not positioned staggered with respect to the second conductor electrodes 5, a substantially continuous conductor element would form as can easily be understood from FIG. 1A. Each cathode 1,2 comprises moreover a plurality of channels 7 which are placed between two adjacent portions of dielectrically insulating material 9 and which pass through the second conductor electrodes 5.

The machine moreover comprises electrical means for generating, between the first 1 and the second 2 cathode, a first transverse electric field T and the second longitudinal electric field L.

The machine comprises moreover supply means 6 for supplying a gaseous mixture 4 in a region of space traversed by the lines of force of the transverse T and longitudinal L electric fields generated by the electrical means; the supply means 6 are preferably apt to supply the gaseous mixture 4 inside a volume circumscribed between the first cathode 1 and the second cathode 2.

The two cathodes 1 and 2 are positioned opposite one to the other and are maintained at an appropriate potential difference necessary for triggering the breakdown of the gaseous mixture 4 and generating the plasma. The two cathodes 1 and 2 are also maintained at an appropriate reciprocal distance which allows, in combination with the potential difference applied, the possibility of modulating the characteristic curve of the plasma generated and, therefore, controlling better the chemical reaction desired.

More specifically the two cathodes 1 and 2 are facing one in relation to the other and define the region of space in whose interior are contained the transverse T and longitudinal L electric fields, when the electrical means apply the potential difference between the first 3 and the second 5 electrodes, and wherein the supply means 6 feed the gaseous mixture 4.

Even more specifically the two cathodes 1 and 2 are arranged in such a way that the first conductor electrodes 3 of the first cathode 1 are at the second conductor electrodes 5 of the second cathode 2, the second conductor electrodes 5 of the first cathode 1 are at the first conductor electrodes 3 of the second cathode 2, the channels 7 of the first cathode 1 are at the first conductor electrodes 3 of the second cathode 2 and the channels 7 of the second cathode 1 are at the first conductor electrodes 3 of the first cathode 2.

Thanks to the configuration of each cathode 1,2, to their position and relative distance as described above as well as to the potential difference applied and to the transverse T and longitudinal L electric fields generated, the gaseous mixture 4 is supplied in a uniform manner exactly in the region of space traversed by the lines of force of the electric fields and a uniform plasma is generated in said region of space. More specifically, thanks to the provision of the channels 7, to their distribution at regular intervals in the cathodes 1,2 and to their position which, traversing the second conductor electrodes 5, is facing the first conductor electrodes 3, the gaseous mixture 4 flows uniformly in all the region of space involved by the plasma and also the composition of the gaseous mixture 4 is found to be uniform.

In this way the deposition is performed on the surface of the substrate S to be treated of chemically ordered and homogeneous thin layers, which is a replacement for conventional processes based on the use of aqueous solutions or of another solvent, wherein an active ingredient, a resin or a chemical product is dispersed.

The substrate S to be treated with the plasma is chosen from among various materials which comprise plastic, metallic, textile, fibrous, synthetic, conductive, vegetal and natural materials.

Each of the channels 7 has a diameter variable between 1 micron and 2 mm, preferably equal to 0.5 mm, so as not to interrupt the at least one electric field generated.

In the first embodiment illustrated in FIG. 1A, the first conductor electrodes 3 and the second conductor electrodes 5 have a flat geometry. However these first conductor electrodes 3 and these second conductor electrodes 5 can have any complex or curved geometry, according to the needs of the specific application.

In the first embodiment illustrated in FIG. 1A, the first conductor electrodes 3 lie on a plane. However the first conductor electrodes 3 and the second conductor electrodes 5 can lie on a circular or otherwise three-dimensional surface, as shown schematically in FIG. 1B, according to the needs of the specific application.

More particularly FIG. 1B represents schematically, in a cross section, some possible alternative embodiments of the cathodes of a machine for the atmospheric plasma treatment of various materials according to the present invention. More particularly the cathodes, rather than both being flat cathodes 1,2, can both have a circular shape 1′,2′ or a circular shape 1″ and the other cylindrical shape 2″ or both polygonal shape 1′″,2′″.

Consequently, as mentioned previously, the first and second conductor electrodes can also be, instead of flat, circular or polygonal.

It is evident that the embodiments illustrated here do not have a limitative scope and, therefore, cathodes and conductor cathodes according to the present invention can assume any other form suitable for achieving the objects of the present invention.

The use of cathodes and electrodes with a circular or cylindrical shape is particularly advantageous in the case of indicating plastic films. The use of cathodes and electrodes with polygonal shape, instead, is particularly advantageous in the cases of rigid substrates or fabric.

The first conductor electrodes 3 are electrodes with high potential connected to a variable potential in the range 1-30 kV, while said second conductor electrodes 5 are earth electrodes connected to the earth of the electrical circuit. The potential difference between the first conductor electrodes 3 and the second conductor electrodes 5 is such as to modulate, in combination with the reciprocal distance between the cathodes 1 and 2, the characteristic curve of the plasma.

As described previously, the machine provides for the two cathodes 1,2 to be opposite and arranged in such a way that to each second conductor electrode, or earth electrode, 5 corresponds frontally a first conductor electrode 3 with higher potential. This arrangement of cathodes and of electrodes allows the generation of two plasma generator electric fields, a first transverse field T, which interacts with both cathodes frontally, and a second longitudinal field L. The potential difference of the reciprocal electrodes 3,5, the type of material used for these electrodes 3,5 (for example whether more or less porous) and the passage or the failed passage of gas allow the possibility of modulating the characteristic curve of the plasma generated and, therefore, a better control of the chemical reaction of the plasma.

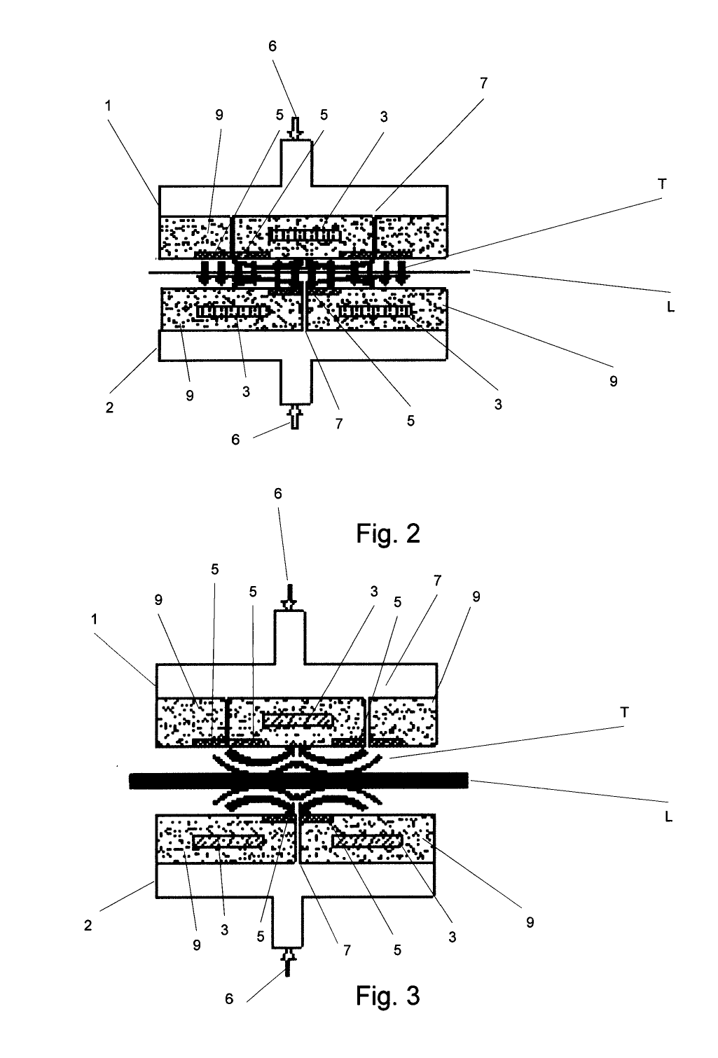

Referring to FIG. 2, it is observed that when the distance between the two cathodes is minimum, the transverse electric field T is prevalent.

Referring to FIG. 3, it is observed that when the distance between the two cathodes is maximum, the longitudinal electric field L is prevalent.

It is considered important to note that, in both the configurations illustrated in FIGS. 2 and 3, the substrate S to be treated is completely and uniformly impacted by the transverse T and longitudinal L electric fields and, therefore, the chemistry of the plasma is constantly controlled and regulated by the electrical parameters of the system. In particular a control is obtained of the chemistry of the plasma which is decidedly higher (of the order of at least 90% more) compared to a plasma jet system, wherein the plasma generated between two electrodes is transferred to a successive zone, i.e. outside of the region of space where the electric fields are present, in order to meet the substrate S, so that the uncontrolled decay of the species activated occurs. Preferably, the machine according to the present invention can also comprise therefore a control unit apt to regulate the electrical means in such a way that the chemistry of the plasma is maintained uniform and the uncontrolled decay of the species activated does not occur.

Preferably the cathodes 1,2 are heat regulated so as to prevent the condensation of the substances which, in the gaseous phase, reach the region of space of the plasma.

The first 3 and second 5 conductor electrodes are made in conductor material, preferably in metallic material or carbon fibre, more preferably in copper, aluminium, silver or carbon fibre.

The portions of dielectrically insulating material 9 are preferably made in silicone, ceramic or composite material.

The machine according to the present invention can treat with atmospheric plasma various materials, such as fabrics and nonwovens of vegetal, natural, synthetic and technical fibres (carbon and glass), plastic, wood, metal. In particular the machine according to the present invention is revealed to be particularly useful in the preparation, for successive and complementary operations, of the surfaces of materials, in particular textile substrates in the form of yarns, fabrics, nonwovens, plastic films, panels, powders and substrates with irregular and complex surfaces, such as finished and three-dimensional objects.

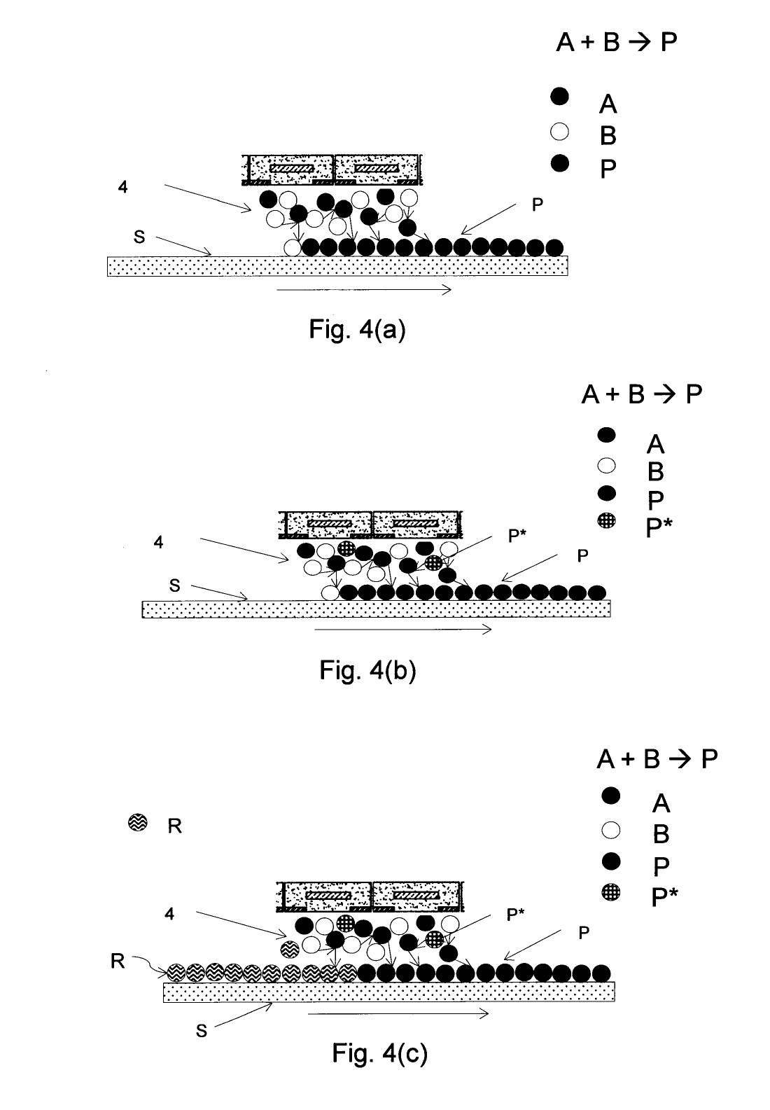

More specifically two or more chemicals and/or monomers and/or precursors, brought into plasma phase in the form of excited molecules maintaining their chemical structure, react one with the other, depositing on the surface of the material the chemical product of the reaction and creating a functional covering on the surface. The reactions are similar to those of polymerisation obtained with classic synthesis methods. This phenomenon is illustrated in FIG. 4(a), wherein A and B denote the molecules of monomer/precursor/chemical substance (in particular A and B are chemical reagents such as, for example, silanes (A) and siloxanes (B) and wherein P denotes the polymer molecules (for example P is polysiloxane). Moreover, as a layer of active ingredient is being deposited on the substrate S, it interacts with the plasma which excites the molecules of the active ingredient, making them react with the monomer/s present in the same plasma and on the surface of the material and redepositing the resulting reaction products. This phenomenon is illustrated in FIG. 4(b), wherein A and B denote the molecules of monomer/precursor/chemical substance as previously identified, P denotes the molecules of polymer as previously identified and P* denotes the molecules of polymer in the form of radical, that is to say the molecules of excited active ingredient.

In another embodiment of the invention the monomer/precursor/chemical substance is applied on the material by means of any technique, such as spray, rotary, impregnation and exposed to the atmospheric plasma obtained from gaseous mixtures containing one or more monomers/precursors/chemical substances. The covering interacts with the plasma which excites the molecules thereof, making them react with the monomers/precursors/chemical substances present in the same plasma and redepositing the resulting reaction products. This phenomenon is illustrated in FIG. 4(c), wherein A and B denote the molecules of monomer/precursor/chemical substance as previously identified, P denotes the molecules of polymer as previously identified and P* denotes the molecules of polymer in the form of radical, that is to say the molecules of excited active ingredient, and R denotes the molecules of a covering, optionally provided on the substrate S. It is underlined that the substrate S covered by the covering R can be subjected to successive drying by means of an oven or IR rays in order to allow the evaporation of the solvent wherein R has been dissolved or be left wet, i.e. without removing the solvent molecules.

The processes described can take place on a single face of the material or on both. As base gas or carrier of the gaseous mixture 4 helium, argon, nitrogen or krypton can be used for example. The machine according to the invention operates in a regime of glow discharge (GD), dielectric barrier discharge (DBD), surface discharge (SD) or crown.

With the machine of the invention, wherein the gaseous mixture comprises the active ingredient required, it is possible to deposit uniformly on the surface of the substrate chemically ordered and homogeneous thin layers of this active ingredient, without the need to use aqueous solutions or of another solvent wherein to disperse this active ingredient.

Advantageously, therefore, the active ingredient does not have to be fixed, as instead takes place in traditional systems via reactions of cross-linking or chemical activation necessary for making the chemical structure of the polymer applied stable and its anchorage to the substrate, for which thermal energy, UV rays or catalysts are used. With the machine of the invention, therefore, the passages indicated above, typical of traditional systems, are eliminated, in that the depositing and fixing are performed in the same passage, eliminating the use of solvents and the correlated excess of chemical products. Moreover the energy used for the entire treatment is considerably reduced, like the physical space of the plant.

By way of an example a water- and oil-repellent surface is considered, which is traditionally obtained by impregnating the fabric with a solution of precursors containing fluorine and then heating to 150° C. in order to obtain the final effect of repellence. Instead, with the present invention, the surface is made water- and oil-repellent by inserting the precursors containing fluorine in the gaseous mixture and/or on the surface of the material by means of a system of covering (spray, impregnation, rotogravure) and injecting the gaseous mixture exactly and uniformly in the region of the electric fields, where these precursors react with the surface so as to create an ordered and repeated structure, functional for the obtaining of the final effect, without the need for successive heating.

Again by way of an example, the case of the preparation of a fabric for printing is considered. According to traditional systems, in order to obtain the definition required, the surface of the substrate has to be covered with a functional layer, for example with urea, to create the environment chemically suitable for the dye. Instead, with the present invention, it is possible to prepare the surface of the substrate by depositing a thin layer chemically compatible with the dye used, this attributing superior performances in terms of definition and reducing at the same time the consumption of water and energy and production cycles.

The machine of the invention is suitable for being integrated in existing machines. In this way productions that are performed by means of the sequence of several stand-alone processes can be integrated in one single machine.

With the machine of the invention the effects required by the market can be conferred to the substrates to be treated such as, for example, antimicrobial, anti-mould, adhesion.

Again by way of an example the case is considered of the treatment of a substrate already covered by a layer of precursors or monomers which need a phase of activation or polymerisation wherein a catalyst is involved which, however, can present problems of conservation (dark, temperature) and of handling (precise times and quantities). Instead, with the present invention, it is possible to make the desired reaction occur by bringing a catalyst into plasma phase and making the covered substrate react.

Again by way of an example, the case is considered of reactive inks which need activation with processes of alkalinisation or vaporisation. Instead, with the present invention, it is possible to make the chemical reaction occur inside the region of space wherein the plasma is generated.

Moreover it is possible to apply the machine of the present invention in order to determine effects of etching or functionalisation, typically performed in atmospheric plasma systems.

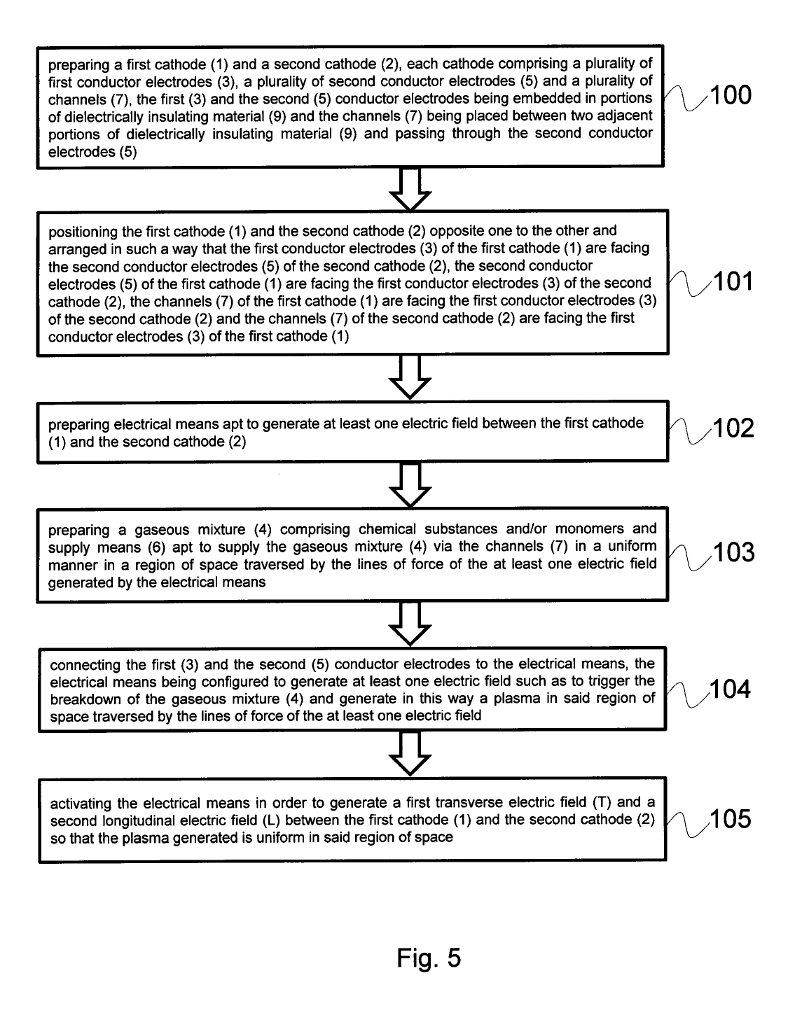

According to another aspect of the invention and referring to FIG. 5, a first embodiment is illustrated of the process for the atmospheric plasma treatment of various materials, comprising the following steps:
a. preparing a first cathode 1 and a second cathode 2, each cathode comprising a plurality of first conductor electrodes 3, a plurality of second conductor electrodes 5 and a plurality of channels 7, the first 3 and the second 5 conductor electrodes being embedded in portions of dielectrically insulating material 9 and the channels 7 being placed between two adjacent portions of dielectrically insulating material 9 and passing through the second conductor electrodes 5 (step 100);
b. positioning the first cathode 1 and the second cathode 2 opposite one to the other and arranged in such a way that the first conductor electrodes 3 of the first cathode 1 are facing the second conductor electrodes 5 of the second cathode 2, the second conductor electrodes 5 of the first cathode 1 are facing the first conductor electrodes 3 of the second cathode 2, the channels 7 of the first cathode 1 are facing the first conductor electrodes 3 of the second cathode 2 and the channels 7 of the second cathode 2 are facing the first conductor electrodes 3 of the first cathode 1 (step 101);
c. preparing electrical means apt to generate at least one electric field (step 102);
d. preparing a gaseous mixture 4 comprising chemicals and/or monomers and supply means 6 apt to supply the gaseous mixture 4 through the channels 7 in a uniform manner in a region of space traversed by the lines of force of the at least one electric field generated by the electrical means (step 103);
e. connecting the first 3 and the second 5 conductor electrodes to the electrical means, the electrical means being configured to generate at least one electric field such as to trigger the breakdown of the gaseous mixture 4 and generate in this way a plasma in said region of space traversed by the lines of force of the at least one electric field (step 104);
f. activating the electrical means in order to generate a first transverse electric field T and a second longitudinal electric field L between the first cathode 1 and the second cathode 2 so that the plasma generated is uniform in said region of space (step 105).

In step 102 the at least one electric field is generated between the first cathode 1 and the second cathode 2 or, in the presence of a substrate S to be treated, between one of the two cathodes (i.e. either the first cathode 1 or the second cathode 2) and the substrate S or both between the first cathode 1 and the substrate S and between the second cathode 2 and the substrate S.

Optionally the substrate S to be treated can be covered with a covering R (as can be seen in FIG. 4(c)) which can be dry or wet, and which can be applied with known techniques such as spray, lamination, rotary printing.

In this optional case between the step c. (step 102) and the step d. (step 103) of the process described above, the additional step is provided of covering the substrate with a dry or wet covering.

A dry covering is preferably constituted by the molecules of chemical precursor and/or of chemical substance. It is applied by impregnation, rotogravure, ink jet, lamination, coating. A wet covering is preferably constituted by the molecules of chemical precursor and/or of chemical substance and by the molecules of solvent wherein it is dissolved and is applied by means of impregnation, rotogravure, ink jet, lamination, coating. The degree of humidity of the substrate is comprised between 1% and 30% in weight, preferably between 2% and 10% in weight.

A second, more general, embodiment of the process for the atmospheric plasma treatment of various materials according to the present invention comprises the steps of:
preparing a substrate S to be treated, said substrate S being rigid, flexible, planar, three-dimensional, with, or also without, a covering of one or more chemical substances of any nature by means of any technique comprising, but not limited to, spray, impregnation, rotogravure;
preparing a gaseous mixture 4 and at least one chemical substance A, B, identical to or different from the chemical substance/s of the covering as above;
selecting the working parameters of the system and of the control of the electric field according to what has been described previously and bringing into plasma phase said gaseous mixture 4, in this way exciting the molecules of said at least one chemical substance A, B, maintaining the chemical structure thereof;
making react one with the other the molecules of said at least one chemical substance A, B and making deposit on the surface of the substrate S the chemical product of the reaction, thus creating a functional covering on the surface. The reactions are similar to those of polymerisation obtained with the classic methods of synthesis;
exposing the substrate S, with or without covering, to the atmospheric plasma created by the gaseous mixture 4 selected.

Optionally it is subsequently possible to expose the substrate S to a further covering with chemical substance/s to confer the final property required.

Preferably, in the processes according to the invention, the gaseous mixture 4 comprises chemicals and/or monomers chosen in the group comprising amines, carboxylic acids, acrylates, silanes, siloxanes, alcohols, ketones.

Preferably, in the processes according to the invention, the first transverse electric field T and the second longitudinal electric field L are of such intensity as to modulate the characteristic curve of the plasma.

Preferably, in the processes according to the invention, the first cathode 1 and the second cathode 2 are heat regulated so as not to cause condensation of the components of the gaseous mixture 4 which reaches the zone of the plasma. In particular the cathodes are heated with variable temperature so as to encourage and accelerate the process of polymerisation and/or deposition of the pre-deposited or vaporised chemical substances.

Preferably, in the processes according to the invention, the various materials which can be treated with the plasma are impacted by the gaseous mixture 4 inside a volume circumscribed between the first cathode 1 and the second cathode 2 and between the material and one of the same cathodes.

Preferably, in the processes according to the invention, the various materials which can be treated with the plasma comprise surfaces of various materials, in particular textile substrates in the form of fibres, yarns, fabrics, nonwovens, plastic films, panels, powders and substrates with irregular and complex surfaces, such as finished and three-dimensional objects.

Preferably, in the processes according to the invention, the electrical means are regulated by means of a control unit, in such a way that the chemistry of the plasma is maintained uniform and the uncontrolled decay of the species activated does not occur.

The processes according to the present invention can use different types of base gases or carriers, such as for example He, N₂, O₂, H₂, Ar, SF₆, Kr and the like. In particular, according to the present invention, an atmospheric plasma is used, generated by two parallel cathodes not closed in a chamber with controlled atmosphere.

The processes according to the present invention are characterised in that the chemical product (monomer, catalyst or reactant) is inserted directly in the zone wherein the plasma is generated as vapour and not sprayed as aerosol. A heat-regulated vaporiser allow controlled and complete evaporation of the chemical product.

The chemical product vapour is mixed with the gas, which acts as carrier, in a chamber and conveyed in a mixture in the zone where the electric field is present.

This peculiar feature modifies in an evident manner the chemical reactivity of the species that are formed, radical and ionic, and consequently also the chemical uniformity and the thickness of the deposit.

According to the present processes it is possible to insert chemical substances with particular functions (catalytic, flameproof, anti-mould, etc.) able to react with the substrate whether virgin, pre-treated with plasma or pre-deposited.

The machine and the processes according to the present invention have a high flexibility in creating the environment suitable for making exclusively the chemical reactions required take place.

The correct energy contribution is supplied in a selective manner on the basis of the energy of the bond which has to be activated and/or split. This is possible by modulating the type of plasma generated, whether it is of the continuous or pulsed type, and varying the resonance frequency, the density and the power thereof.

The possibility of using a vast range of gas, with different chemical nature and with variable percentage of species, can considerably influence the environment of reaction, creating, according to the cases, a system with oxidating or reductive properties.

Moreover the possibility of inserting the chemical product directly in the zone of the plasma gives rise to a different interaction of the plasma with the carrier gas, the chemical product and the substrate itself.

The following reactions are possible.

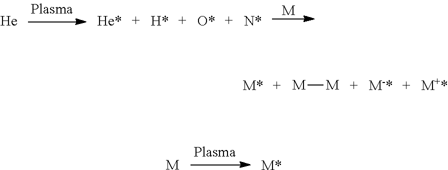

wherein: M is the chemical product, monomer

According to the first reaction the electric fields present inside the plasma excite the molecules of the carrier gas (He, N₂, O₂, H₂, Ar, SF₆, Kr and the like) generating radicals of the species present, such as for example He*, N*, O*, and the like. These species, highly reactive, in turn excite the chemical product molecule: in this way mixed species between gas and monomer are also created, harmful for the depositing, and it is very difficult to control the deposit and its chemical composition. According to the second reaction the electric field of the plasma itself excites the monomer, generating species M* in large quantities. In these conditions the formation of fragmented species is reduced and the selectivity and the purity of the deposited layer is decidedly higher.

Using chemical products M with particular properties it is possible to carry out chemical reactions such as to integrate selectively with the virgin or pre-treated substrate with chemical substances. The chemical reactivity of this complex system takes on a fundamental role in the deposit which is created and it is a combination between the action of the plasma, of the excited gas, of the vaporised chemical product and of the chemical substances pre-deposited on the substrate.

In the specific case of chemical products with particular chemical functions (for example with double bonds) tests were carried out both for the pre-treatment on the substrate and for the direct vaporisation in the plasma and it was found that the energy supplied by the plasma is functional to the breakage of the double bond of the chemical product, as results from the following reaction:

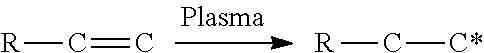

The radical which is formed is strongly reactive in respect of the substrate, whether it is of polymer or textile nature, optionally appropriately pre-treated in order to make its affinity greater. Using chemical substances in aqueous solution there is also an interaction of the molecule of H₂O excited (H₂O*) with the species of excited chemical product R—C—C*: these species encourage the reaction of the chemical product with the substrate.

Moreover, as will be described in greater detail in Example 2, plasma treatments were tested with anti-mould chemical products with generic formula:

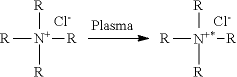

The product was tested:

1. as substance deposited on the substrate which subsequently was treated with the plasma after drying or directly wet,
2. as product vaporised directly in the plasma zone.

In these cases too the radical species which are formed are strongly reactive on the surface of the substrates used. The formation of a stable bond between the substrate and the anti-mould product eliminates drastically the problem of the release of the product and the consequent decay of the anti-mould effect.

According to another aspect of the invention, a gaseous mixture 4 is illustrated, which can be used for the plasma treatment of various materials comprising in a non-exclusive manner chemicals and/or monomers chosen in the group comprising amines, carboxylic acids, acrylates, silanes, siloxanes, alcohols, ketones.

The gaseous mixture preferably comprises, as chemical substance for the anti-mould treatment, quaternary ammonium salts, such as for example alkyl benzyl ammonium.

Preferably, in the gaseous mixture according to the invention, the monomers/gaseous mixture ratio varies between 0.1% and 20% in volume, and is preferably equal to 5% in volume.

In a further embodiment the machine, the processes and the gaseous mixture according to the invention allow the treating of a substrate already covered by a layer of precursors or monomers, whether the substrate is wet or dry, which require successive activation or polymerisation by means of a catalyst.

The invention described here is illustrated by means of the following examples, given purely by way of an example and not to be understood as limited.

### Example 1: Anti-Stain Properties

The processes for conferring anti-stain properties to fabrics are performed using fluorocarbon resins with long chain.

In recent years these processes have attracted the attention of environmental laws in that high concentrations of perfluorocarbon acids with chain with 8 atoms of C (C8) have been identified in the waters of rivers and seas, deriving from the washings of fabrics treated with these resins and from the disposal of the effluent of textiles companies. Perfluorocarbon acids are harmful for the aquatic fauna and traces have also been found in the blood of a sample of people, to indicate how these substances can easily and rapidly spread and pose severe problems of public and environmental health.

The approaches for limiting and/or eliminating this phenomenon are mainly the reduction of the quantity of fluorocarbon resins used and the development of resins which release perfluorocarbon acids with short chain (C4 and C6), considered non-harmful for humans and for the environment. The second solution is definitely the more sustainable, however the resins developed with base C4 and C6 confer to the fabrics inferior anti-stain properties than traditional resins with C8 base.

The atmospheric plasma process according to the present invention was used for the anti-stain treatment of fabrics using fluorocarbon precursors with short chain and obtaining the same performances achieved with the use of resins with C8 base, as described here below. Moreover, with the atmospheric plasma process according to the present invention it was found to be possible to use a lower quantity of precursors than the traditional applications of resins, thus drastically reducing the quantity of water used for their application and significantly limiting the problem of effluent.

A fluorocarbon precursor, chosen from within the class of acrylate and methacrylate monomers containing a number of —CFₓ groups comprised between 1 and 6, was diluted in a suitable solvent, preferably water, in a concentration comprised between 1% and 10% in weight.

The general structure of the precursors, R—CH₂—COO—(CF₂)ₘ—CF₃ highlights the presence of a double bond able to react and start up reactions of polymerisation and of cross-linking. These reactions are generally initiated by supplying energy to the molecule, whether it is in the form of thermal energy or in the form of radical molecules which split the double bond and launch the chain of typical reactions of radical polymerisation. The use of a catalyst lowers the energy of activation of the reaction and allows, traditionally, the use of less severe conditions, such as for example lower temperatures.

The active species created in the plasma, such as energy molecules, radicals and electrons, have the same function as the radicals or of the temperature used in the classic reactions of polymerisation/cross-linking and can therefore initiate chain reactions, attacking and reacting with the double bond of the acrylic structure.

The fluorocarbon precursor is applied to a fabric in polyester by means of the spray technique or impregnation or gravure technique or coating or lamination or rotary printing and ink jet.

The quantity of solution of the precursor deposited on the fabric is comprised between 2 g/m² and 10 g/m².

The fabric prepared in this way is subjected to the process of atmospheric plasma treatment according to the present invention, exposing it to a helium or helium and oxygen plasma. By way of comparison the fabric prepared as mentioned previously was also subjected to no plasma.

The treatment was performed continuously, at speeds of 5, 10 and 15 metres/minute, with power of 8,000 W.

The fabric treated in this way was evaluated immediately after the treatment and the subsequent day using the method of the angle of contact according to the AATCC 118 standard to evaluate the effect conferred. Two reference liquids were used, distilled water and oil. The samples were also evaluated after repeated washes in water and dry (washing with solvent).

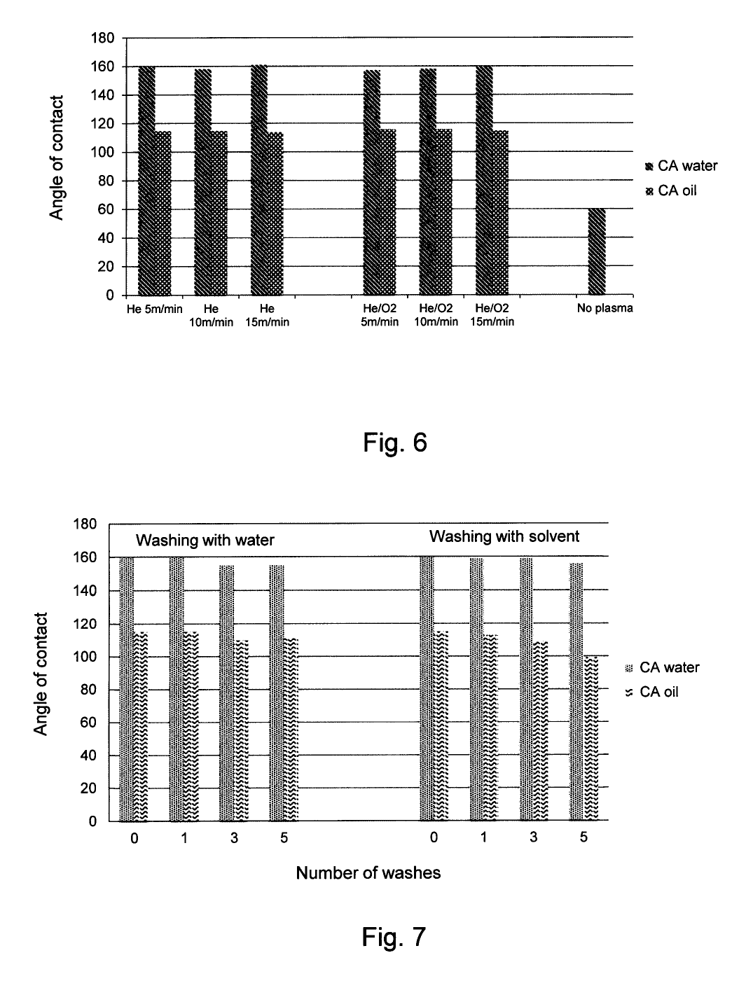

Referring to FIG. 6, it is observed that the fabrics subjected to treatment with plasma (of helium and of helium and oxygen at the different speeds indicated above) have angles of contact greater than 150° for water and 110° for oil, demonstrating anti-stain and anti-water properties. As can be seen, the speed does not influence the result. Instead the fabric impregnated with precursor but not treated with plasma has values of water- and oil-repellence similar to the virgin fabric, much lower than the fabrics treated with the process according to the present invention. Comparable values are also shown 24 hours after the treatment (values not shown in the graph). Referring to FIG. 7, it is observed that the washing with water and with solvent, also repeated, does not substantially modify the values of angle of contact. In the graph the data have been given of the fabric treated with helium plasma at a speed of 15 metres/minute.

### Example 2: Anti-Mould Properties

The anti-mould products preferably used in the process according to the present invention belong to the class of quaternary ammonium salts with general formula:

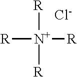

The quaternary ammonium is an organic cation of general formula R₄N⁺, in which a nitrogen atom with positive charge is directly bonded to four organic substitute groups R. The organic groups R can be methyl, ethyl, propyl, etc., while the counterion can be any element belonging to the class of the halides, preferably Cl and Br.

This type of anti-mould products is commonly used on different substrates since it is highly effective against a large variety of micro-organisms, germs and bacteria. The recommended doses vary between 0.05% in weight (light disinfection) and 0.2% in weight (generic disinfectant of plants).

This type of anti-mould products moreover is perfectly stable both in concentrated form and after dilution also in boiling water.

Moreover the surfactant properties of this type of anti-mould products are visibly apparent in the facilitating of the penetration of the liquid in gaps, including capillary ones, where the water would not arrive, to reach or hit the micro-organisms. The lowering of the surface tension of the water allows in fact the wetting of greasy and dirty surfaces and the penetration everywhere, this being an essential basis for obtaining a perfect disinfecting action.

As anticipated, the anti-mould products were tested using the process according to the invention.

1. as substance deposited on the substrate which subsequently was treated with the plasma after drying or directly wet, and
2. as product vaporised directly in the plasma zone.

The plasma can also be used in the preliminary preparation of the substrate in order to make the fibre and/or the fabric, vegetal or animal, have a chemical affinity with the anti-mould product used in the subsequent treatments of impregnation. This is typically done with aggressive chemical treatments which provide for the use of chemical substances harmful to the environment in which the plasma, therefore, is found to be an alternative and ecologically compatible solution for the treatment of the fibre and/or of the fabric.

In this example different types of gas He, N₂, O₂, H₂, Ar, SF₆ and the like were used, appropriately modulating the power and consequently the density of the plasma. In particular a series of derivatives of the alkyl benzyl ammonium type with general formula were used:

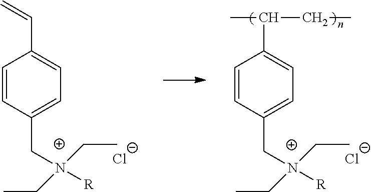

wherein the hydrophobia/hydrophilia ratio could be modulated as required, modifying the solubility thereof in the solvents.

The vinyl group is then suitable for being polymerised by means of atmospheric plasma as in the case of surfactants which can be polymerised, obtaining the filming of the fibre which, expressing positive charges of the ammonium type, becomes antibacterial and anti-mould.

A further advantage of the chemical compound cited is its good solubility in water. Tests of solubility in water have led to the preferring of the compound wherein the substitute R is made up of an ethyl group, and with this compound a stock solution was prepared in water at 50% in weight. For dilution of the stock solution with different volumes of water, a series of solutions was prepared (40%, 30%, 20%, 10%, 5% and 1%, percentages in weight).

The process according to the present invention provides a preliminary spray treatment with the solution of the antibacterial, so that the dispersibility was tested on various different fibres via spray as a function of the viscosity compatibly with the distribution of the maximum quantity of antibacterial/anti-mould agent. The best dilution was found to be that at 10% in weight.

Tests of antibacterial and anti-mould activity were performed on samples treated with three different strains chosen as model strains in order to evaluate to what extent the plasma treatments and the application of the additive influence the bacterial and fungal growth. The results of these tests are given in the following table and show a significant abatement, greater than 2 logarithm units in the case of samples treated with the plasma C4 (Δ log A=3.10 for the Klebsiella pneumoniae strain; Δ log A=3.62 for Staphylococcus aureus; Δ log A=2.89 for Candida albicans) and C5 (Δ log A=2.64 for the Klebsiella pneumoniae strain; Δ log A=2.09 for Staphylococcus aureus; Δ log A=2.96 for Candida albicans).

| | | Klebsiella | Staphylococcus | Candida |
|---|---|---|---|---|
| | | pneumoniae | aureus ATCC | albicans |
| Sample | Treatments | ATCC 10031 | 6538P | ATCC 13231 |
| Ref. | Wool fibre, as is | 8.5 × 108 | 1.1 × 109 | 8.3 × 108 |
| | | (8.93) | (9.04) | (8.92) |
| C1 | Wool fibre treated | 1.2 × 109 | 7.3 × 108 | 6.7 × 108 |
| | only with plasma 1 | (9.08) | (8.86) | (8.83) |
| C3 | Wool fibre treated | 1.3 × 108 | 8.7 × 108 | 4.8 × 108 |
| | with only | (8.11) | (8.94) | (8.68) |
| | antibacterial agent | | | |
| C4 | Wool fibre treated | 7.9 × 105 | 2.4 × 105 | 1.3 × 106 |
| | with plasma 1 + | (5.90) | (5.38) | (6.11) |
| | antibacterial | | | |
| | agent + | | | |
| | plasma 2 | | | |
| C5 | Wool fibre treated | 2.3 × 106 | 8.1 × 106 | 1.1 × 106 |
| | with antibacterial | (6.36) | (6.91) | (6.04) |
| | agent + plasma 2 | | | |

The effect of the plasma on the antibacterial product is clear by comparing the samples C3 and C5 from the point of view of the antibacterial action on the various strains taken into examination.

### Example 3: Flameproof Properties

The flameproof chemical products preferably used in the process according to the present invention are chemical products used to make the fabrics particularly resistant to combustion. Among these the main ones are inorganic salts (ammonium phosphates, alkaline silicates, sodium stannate, etc.), chlorinated naphthalenes and paraffins, polyvinyl chloride.

More particularly all three large families of flame-retardant products in use today were used, that is to say:
inorganic products such as aluminium trihydroxide, magnesium hydroxide, ammonium polyphosphate and red phosphorus;
halogenated products, based mainly on chlorine and bromine;
organophosphoric products, above all phosphate esters, having formula:

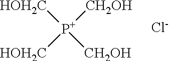

The flameproof products used, when subjected to the action of a flame, act, on the one hand, by liberating acid on the fibre, damaging the fabric in the area of application of the flame and avoiding the release of flammable gases and, on the other hand, inhibiting the continuation of the combustion since they release non-combustible gases.

The methodology of traditional application provides different phases: impregnation, drying and polymerisation, alkaline scrubbing and finally final drying.

Instead the process according to the present invention, thanks to the use of the plasma, allows a reduction in the number of steps to be performed and a shortening of the time necessary for the entire application cycle. In particular the times of impregnation and drying are reduced, the type of polymerisation is considerably reduced (from some minutes to some seconds) and the step of alkaline scrubbing is eliminated.

Similarly to the anti-mould products as per Example 2, the flameproof products were tested using the process according to the invention:

1. as substance deposited on the substrate which subsequently was treated with the plasma after drying or directly wet,
2. as product vaporised directly in the plasma zone.

In general, for the products tested, the quantity of solution of the precursor deposited on the fabric is comprised between 2 g/m² and 5 g/m²; the product is dissolved in an appropriate solvent, preferably water, in a quantity varying between 5 and 300 g/l. The temperature of drying and polymerisation varies from 80 to 150° C. according to the type of substrate impregnated. The times of polymerisation vary from 2 minutes to 60 minutes. The speed varies from 1 metre/minute to 10 metres/minutes.

The flameproof tests were performed according to the standard EN 17025 and tests of fastness to washing (DIN 53920) and fastness to dry cleaning were also carried out.

The fastness to washing was brought to values higher than the standard limit value reached of 1.4% in weight also after 25 washes. The values found using the plasma in the process vary from 1.9 to 1.6% in weight.

The fastness to dry cleaning was also brought to values higher than the standard limit value reached of 1.4% in weight also after 25 washes. The values found using the plasma in the process vary from 1.85 to 1.55% in weight.

As regards the flameproof tests, different methods of testing were developed and used which differ one from the other by degree of complexity, starting from the simplest (for example ASTM D 2863 and UL 94, with test pieces 10 cm in length), up to somewhat articulated methods (such as ASTM E 84, which provides for test pieces 750 cm long).

The tests with direct flame provide for the evaluation of the behaviour of the substrate treated under various aspects:

1. time of propagation of the flame;
2. presence of a hole in the fabric and dimensions of the hole;
3. burning of the edges;
4. fall of debris with presence or otherwise of incandescent debris.

The results obtained on samples treated according to the present invention are good from all points of view. In particular the samples treated with plasma have a shorter time of propagation, smaller dimensions of the hole (at times the hole is not observed), a smaller burning of the edges and a very low quantity of debris.

### Example 4: Ink Jet Printing

The fabrics have to be prepared before the printing process, rotary or digital. The process of preparation implies the cleaning of the fibre and/or the application of resins or pastes functional for successive printing. The phase of preparation serves to increase the affinity of the fibre for the ink or the pigment used, to improve the definition of printing and to increase the resistance of the printing to washes and rubbing. The phase of preparation is also functional to the use of inks and pigments dissolved in aqueous solution in order to replace those dissolved in solvent. The traditional preparation methods are based on the technique of impregnation of the foulard type and successive cross-linking and drying, passages which can also reach 130-150° C. The traditional methods require long times and a very high use of energy and water, generating at the same time toxic substances and contaminated waters which represent serious environmental problems.

The preparation of the fabrics for the printing process can therefore, advantageously, be performed by means of the plasma process according to the present invention.

A mixture of precursors chosen from within the class of the silanes, having general structure R(CH₂)—Si—X₃, is diluted in a suitable solvent, preferably water/ethanol, in a concentration comprised between 1% in weight and 20% in weight. The functional group R is selected to confer certain required functional features to the printing, such as for example increasing the hydrophobia of the surface or increasing the wettability of the same or creating the possibility of chemically bonding the ink.

The mixture of silanes is applied to a fabric in polyester by means of the spray technique or impregnation or gravure technique or coating or lamination or rotary printing and ink jet.

The fabric prepared in this way is subjected to the process of atmospheric plasma treatment according to the present invention. In particular the fabric is exposed to a plasma generated by a mixture of helium and by a siloxane precursor chosen from among those having general structure R—Si—OX₃. By way of comparison the fabric prepared as mentioned previously was also subjected to no plasma.

The treatment was performed continuously, at speeds of 5 and 15 metres/minute, with power of 8,000 W.

The fabric was then printed with the ink jet technique, using direct inks.

The quality of the printing was then evaluated in terms of definition on weft and warp. The printing definition, evaluated in terms of “non soiling” and “non smudging” of the printed pattern is distinctly superior in the case of samples prepared using the plasma process according to the present invention, compared with those prepared traditionally.

The exposition to the mixture of excited gases and of active species, produced by the helium and by the chemical precursor used (siloxane) improve the cross-linking of the mixture applied and its anchorage to the fabric.

The physical properties of the mixture of silanes applied can be altered by the cross-linking of the silane molecules themselves. Certain physical properties can therefore be obtained by controlling the degree of cross-linking which takes place in the mixture. The degree of cross-linking can be determined, for example, by the type of active species (electrons, free radicals, energy gas species) to which the mixture is exposed, by the power of the discharge, by the chemical precursor used in the plasma treatment.

In order to evaluate the degree of cross-linking of the samples, the fabrics prepared with the plasma process according to the present invention were subjected to evaluation of the angle of contact with distilled water in order to be able to compare them with the polyester prepared traditionally. The angles of contact recorded vary between 140° and 155°. This feature is fundamental in order to obtain correct fluid dynamics and the correct absorption of the direct ink used, which determine the quality of the printing.

On the contrary the fabric impregnated with the mixture of silanes precursors and not treated with the plasma exhibits an inferior printing definition, with evident phenomena of smudging. This sample is associated with an angle of contact of approximately 90°.

As further analysis, the resistance to dry and wet rubbing of the printed polyester fabrics was tested using the standard AATCC-08. The results presented in the table below show that the preparation by means of the plasma process according to the present invention allows performances to be obtained that are comparable to those obtained with traditional processes of preparation, yet with the advantage of limiting or eliminating the use of water and the use of drying systems with high energy consumption. The process according to the present invention responds, therefore, to the principles of environmental sustainability.

| Sample | Dry | Wet |
|---|---|---|
| No plasma | 4 | 3/4 |
| Plasma | 4 | 4 |

As is deduced from what is set out above, the innovative technical solution described here has the following advantageous features:
the preparation of surfaces of various materials, in particular textile substrates in the form of fibres, yarns, fabrics, nonwovens, plastic films, panels, powders and substrates with irregular and complex surfaces, such as finished and three-dimensional objects;
the application to operations such as, for example, impregnation, printing (ink jet and traditional), coating, lamination, foaming, spraying;
the obtaining of effects and properties according to the specific need such as, for example, antimicrobial, anti-mould, adhesion behaviour;
the elimination of solvents and the reduction of chemical products, with consequent economic and environmental benefits;
the elimination of catalysts, with consequent solving of the problems of storage and handling;
the reduction in energy and water consumptions in the production cycles;
the containing of the overall dimensions of the plant; and
the adaptation to existing processes and machinery.

From the description given above it is clear, therefore, how the machine, the processes and the gaseous mixture according to the invention described here above allow the objects proposed to be reached.

It is equally evident, to a person skilled in the art, that it is possible to make changes and variants to the solution described with reference to the accompanying drawings, without thereby departing from the teaching of the present invention and the sphere of protection as defined by the appended claims.

1. Machine for the atmospheric plasma treatment of various materials, comprising:
a first cathode (1) and a second cathode (2), each cathode comprising a plurality of first conductor electrodes (3) and a plurality of second conductor electrodes (5) embedded in portions of dielectrically insulating material (9);
electrical means apt to generate at least one electric field between the first cathode (1) and the second cathode (2) or between one of the two cathodes
(1,2) and a substrate (S) to be treated or both between the first cathode (1) and the substrate (S) and between the second cathode (2) and the substrate (S);
supply means (6) apt to supply a gaseous mixture (4) in a region of space traversed by the lines of force of the at least one electric field generated by the electrical means, the electrical means being configured to generate at least one electric field such as to trigger the breakdown of the gaseous mixture (4) and generate in this way a plasma in said region;
characterised in that
the first cathode (1) and the second cathode (2) comprise moreover, each one, a plurality of channels (7) placed between two adjacent portions of dielectrically insulating material (9) and passing through the second conductor electrodes (5), so that the gaseous mixture (4) is supplied in a uniform manner in said region;
the first cathode (1) and the second cathode (2) are positioned opposite one to the other and arranged in such a way that the first conductor electrodes (3) of the first cathode (1) are facing the second conductor electrodes (5) of the second cathode (2), the second conductor electrodes (5) of the first cathode (1) are facing the first conductor electrodes (3) of the second cathode (2), the channels (7) of the first cathode (1) are facing the first conductor electrodes (3) of the second cathode (2) and the channels (7) of the second cathode (2) are
facing the first conductor electrodes (3) of the first cathode (1);
the electrical means generate a first transverse electric field (T) and a second longitudinal electric field (L) between the first cathode (1) and the second cathode (2) so that they generate a uniform plasma in said region of space.

2. Machine according to claim 1, wherein each of said channels (7) has a diameter variable between 1 micron and 2 mm, preferably equal to 0.5 mm, so as not to interrupt the at least one electric field generated.

3. Machine according to claim 1, wherein said first conductor electrodes (3) are electrodes with high potential connected to a variable potential in the range 1-30 kV, wherein said second conductor electrodes (5) are earth electrodes connected to the earth of the electrical circuit and wherein the potential difference between said first conductor electrodes (3) and said second conductor electrodes (5) is such as to modulate the characteristic curve of the plasma.

4. Machine according to claim 1, wherein said first conductor electrodes (3) and said second conductor electrodes (5) have any flat, complex or curved geometry and lie on a plane or on a circular or otherwise three-dimensional surface.

5. Machine according to claim 1, wherein said first conductor electrodes (3) and said second conductor electrodes (5) are made in conductor material, preferably in metallic material or carbon fibre, more preferably in copper, aluminium, silver or carbon fibre.

6. Machine according to claim 1, wherein said portions of dielectrically insulating material (9) are made in silicone, ceramic or composite material.

7. Machine according to claim 1, wherein the supply means (6) are apt to supply the gaseous mixture (4) inside a volume circumscribed between said first cathode (1) and said second cathode (2) and between the material and one of the same cathodes.

8. Machine according to claim 1, wherein the various materials which can be treated with the plasma comprise plastic, metallic, textile, fibrous, synthetic, conductive, vegetal and natural materials.

9. Machine according to claim 1, further comprising a control unit apt to regulate the electrical means in such a way that the chemistry of the plasma is maintained uniform and the uncontrolled decay of the species activated does not occur.

10. Process for the atmospheric plasma treatment of various materials, comprising the following steps:
a. preparing a first cathode (1) and a second cathode (2), each cathode comprising a plurality of first conductor electrodes (3), a plurality of second conductor electrodes (5) and a plurality of channels (7), the first (3) and the second (5) conductor electrodes being embedded in portions of dielectrically insulating material (9) and the channels (7) being placed between two adjacent portions of dielectrically insulating material (9) and passing through the second conductor electrodes (5) (step 100);
b. positioning the first cathode (1) and the second cathode (2) opposite one to the other and arranged in such a way that the first conductor electrodes (3) of the first cathode (1) are facing the second conductor electrodes (5) of the second cathode (2), the second conductor electrodes (5) of the first cathode (1) are facing the first conductor electrodes (3) of the second cathode (2), the channels (7) of the first cathode (1) are facing the first conductor electrodes (3) of the second cathode (2) and the channels (7) of the second cathode (2) are facing the first conductor electrodes (3) of the first cathode (1) (step 101); c. preparing electrical means apt to generate at least one electric field between the first cathode (1) and the second cathode (2) or between one of the two cathodes (1,2) and a substrate (S) to be treated between the first cathode (1) and the substrate (S) and between the second cathode (2) and the substrate (S) (step 102);
d. preparing a gaseous mixture (4) comprising chemicals and/or monomers and supply means (6) apt to supply the gaseous mixture (4) via the channels (7) in a uniform manner in a region of space traversed by the lines of force of the at least one electric field generated by the electrical means (step 103);
e. connecting the first (3) and the second (5) conductor electrodes to the electrical means, the electrical means being configured to generate at least one electric field such as to trigger the breakdown of the gaseous mixture (4) and generate in this way a plasma in said region of space traversed by the lines of force of the at least one electric field (step 104);
f. activating the electrical means in order to generate a first transverse electric field (T) and a second longitudinal electric field (L) between the first cathode (1) and the second cathode (2) so that the plasma generated is uniform in said region of space (step 105).

11. Process according to claim 10, wherein the substrate (S) to be treated can be covered with a dry or wet covering (R).

12. Process for the atmospheric plasma treatment of various materials, comprising the steps of:
preparing a substrate (S) to be treated;
preparing a gaseous mixture (4) and at least one chemical substance or reagent (A, B);
bringing into plasma phase said gaseous mixture (4), in this way exciting the molecules of said at least one chemical substance or reagent (A, B), maintaining the chemical structure thereof;
making react one with the other the molecules of said at least one chemical substance (A, B) and making deposit on the surface of the substrate (S) the chemical product of the reaction, thus creating a functional covering on the surface.

13. Process according to claim 12, wherein said at least one chemical substance or reagent (A, B) is brought into plasma phase by the gaseous mixture both in wet and dry form.

14. Process according to claim 12, comprising the further step of:
making interact the covering deposited on the substrate (S) with the molecules of the active ingredient (P), making them react with the monomer/s (A, B) present in the same plasma and on the surface of the substrate (S), and redepositing the resulting reaction products.

15. Process according to claim 10, wherein said gaseous mixture (4) comprises chemical substances chosen in the group comprising amines, carboxylic acids, acrylates, silanes, siloxanes, alcohols, ketones.

16. Process according to claim 10, wherein said first cathode (1) and said second cathode (2) are heat regulated so as not to make the components of the gaseous mixture (4) which reach the zone of the plasma condensate.

17. Process according to claim 10, wherein the various materials which can be treated with the plasma are impacted by the gaseous mixture (4) inside a volume circumscribed between said first cathode (1) and said second cathode (2) and between the material and one of the same cathodes.

18. Process according to claim 10, wherein the electrical means are regulated by means of a control unit, in such a way that the chemistry of the plasma is maintained uniform and the uncontrolled decay of the species activated both in wet and dry form does not occur.

19. Process as defined in claim 12 where said gaseous mixture (4) which can be used for the atmospheric plasma treatment of various materials comprises chemical substances chosen in the group comprising amines, carboxylic acids, acrylates, silanes, siloxanes, alcohols, ketones.

20. Gaseous mixture (4) according to claim 19, wherein said chemical substances are present in both wet and dry form.
